(19) United States
(12) Patent Application Publication
(10) Pub. No.: US 2025/0199399 A1
(43) Pub. Date: Jun. 19, 2025

(54) PHOTORESIST COMPOSITIONS AND METHODS OF MANUFACTURING INTEGRATED CIRCUIT DEVICES BY USING THE SAME

(71) Applicant: Samsung Electronics Co., Ltd., Suwon-si (KR)

(72) Inventors: Ji Young Park, Suwon-si (KR); Chawon Koh, Suwon-si (KR); Yongbeom Seo, Suwon-si (KR); Heeyoung Go, Suwon-si (KR); Changmin Park, Suwon-si (KR); Wonjoon Son, Suwon-si (KR)

(21) Appl. No.: 18/797,979

(22) Filed: Aug. 8, 2024

(30) Foreign Application Priority Data
Dec. 15, 2023 (KR) 10 2023 0183047

(51) Int. Cl. G03F 7/004; H01L 21/027

(52) U.S. Cl. CPC G03F 7/0042; H01L 21/0274

(57) ABSTRACT

A photoresist composition includes an organometallic complex having a metal element and ligands bonded to the metal element, and a solvent, wherein the ligands includes at least one N,O-β-heteroarylalkenolate ligand having an oxygen atom and a nitrogen atom, which are each directly bonded to the metal element, and at least one monodentate ligand bonded to the metal element. A method of manufacturing an integrated circuit device includes exposing an unshared electron pair of the metal element by exposing, to light, a first area of a photoresist film obtained from the photoresist composition and dissociating the at least one monodentate ligand from the organometallic complex, and forming an organometallic structure network in the first area by inducing crystal growth of bonded structures between the metal element having the unshared electron pair and the at least one N,O-β-heteroarylalkenolate ligand.

### CROSS-REFERENCE TO RELATED APPLICATION

This application claims priority under 35 U.S.C. § 119 to Korean Patent Application No. 10-2023-0183047, filed on Dec. 15, 2023, in the Korean Intellectual Property Office, the disclosure of which is incorporated by reference herein in its entirety.

### FIELD

The inventive concept relates to photoresist compositions and methods of manufacturing integrated circuit devices by using the photoresist compositions, and more particularly, to photoresist compositions that include a metal and methods of manufacturing integrated circuit devices by using the photoresist composition.

### BACKGROUND

Due to the advance of electronics technology, semiconductor devices have been rapidly down-scaled. Therefore, photolithography processes having good effects in implementing fine patterns are used. In particular, it is necessary to develop a photoresist composition capable of providing process stability, excellent etch resistance, and excellent resolution in a photolithography process for manufacturing an integrated circuit device.

### SUMMARY

The inventive concept provides a photoresist composition having improved storage stability, minimizing line-edge roughness (LER) and line-width roughness (LWR), and providing excellent etch resistance and resolution, in a photolithography process.

The inventive concept also provides a method of manufacturing an integrated circuit device, the method being capable of improving the dimensional precision of a pattern intended to be formed by minimizing LER and LWR and providing excellent etch resistance and resolution.

According to an aspect of the inventive concept, there is provided a photoresist composition including an organometallic complex, which includes a metal element and a plurality of ligands bonded to the metal element and including at least two different ligands, and a solvent, wherein the plurality of ligands of the organometallic complex include at least one N,O-β-heteroarylalkenolate ligand having an oxygen atom and a nitrogen atom, the oxygen atom and the nitrogen atom each directly bonded to the metal element, and at least one monodentate ligand bonded to the metal element.

According to another aspect of the inventive concept, there is provided a photoresist composition including an organometallic complex and a solvent and configured to have a structural change of the organometallic complex in response to exposure to light, wherein the organometallic complex includes a metal element and a plurality of ligands bonded to the metal element and including at least two different ligands, and the plurality of ligands include two N,O-β-heteroarylalkenolate ligands each having an oxygen atom and a nitrogen atom, the oxygen atom and the nitrogen atom each directly bonded to the metal element, and at least one monodentate ligand including a C1 to C20 hydrocarbon group directly bonded to the metal element, the at least one monodentate ligand being configured to be dissociated (e.g., capable of dissociating) from the metal element in response to exposure to light.

According to another aspect of the inventive concept, there is provided a method of manufacturing an integrated circuit device, the method including forming a photoresist film on a substrate by using a photoresist composition including a plurality of organometallic complexes and a solvent, wherein each of the plurality of organometallic complexes includes a metal element and a plurality of ligands bonded to the metal element and including at least two different ligands, and the plurality of ligands of each of the plurality of organometallic complexes include at least one N,O-β-heteroarylalkenolate ligand having an oxygen atom and a nitrogen atom, the oxygen atom and the nitrogen atom each directly bonded to the metal element, and at least one monodentate ligand bonded to the metal element, exposing an unshared electron pair of the metal element by exposing a first area to light, which is a portion of the photoresist film, and thus by dissociating the at least one monodentate ligand from each of the plurality of organometallic complexes selectively only in the first area of the photoresist film, forming an organometallic structure network in the first area by inducing crystal growth of bonded structures between the at least one N,O-β-heteroarylalkenolate ligand and the metal element, which has the unshared electron pair that is exposed, in the first area exposed to light, and forming a photoresist pattern including the organometallic structure network by developing the photoresist film in which the organometallic structure network is formed.

### BRIEF DESCRIPTION OF THE DRAWINGS

Embodiments will be more clearly understood from the following detailed description taken in conjunction with the accompanying drawings in which:

FIG. 1 is a flowchart illustrating a method of manufacturing an integrated circuit device, according to some embodiments;

FIGS. 2A to 2F are cross-sectional views illustrating a sequence of processes of a method of manufacturing an integrated circuit device, according to some embodiments;

FIG. 3 is a diagram illustrating a structural change of an example organometallic complex in a region of a photoresist film before and after exposing the region of the photoresist film to light in a method of manufacturing an integrated circuit device, according to some embodiments; and

FIG. 4A is a diagram illustrating example organometallic complexes in a region NEX of FIG. 2B, and FIG. 4B is a diagram illustrating example organometallic complexes in a region EX of FIG. 2B.

### DETAILED DESCRIPTION OF THE EMBODIMENTS

Hereinafter, embodiments of the inventive concept will be described in detail with reference to the accompanying drawings. Like components are denoted by like reference numerals throughout the specification, and repeated descriptions thereof are omitted.

A photoresist composition according to some embodiments includes an organometallic complex, which includes a metal element and a plurality of ligands bonded to the metal element and including at least two different ligands, and a solvent. In the photoresist composition according to some embodiments, the plurality of ligands of the organometallic complex may include at least one N,O-β-heteroarylalkenolate ligand and at least one monodentate ligand. The at least one N,O-β-heteroarylalkenolate ligand has an oxygen atom and a nitrogen atom, the oxygen atom and a nitrogen atom each directly bonded to the metal element, and the at least one monodentate ligand is bonded to the metal element.

In the organometallic complex of the photoresist composition according to some embodiments, the type of bond between the metal element and the plurality of ligands is not particularly limited. For example, the bond between the metal element and the plurality of ligands may include a covalent bond, a coordination bond, or an ionic bond. The photoresist composition according to some embodiments has a heteroleptic structure, in which a plurality of ligands including at least two different organic ligands are bonded to a metal element.

In the photoresist composition according to some embodiments, the metal element of the organometallic complex may include a metal having a coordination number of 5 or 6. For example, the metal element may include Sn, Sb, In, Bi, Ag, Te, Au, Pb, Zn, Ti, Hf, Zr, Al, V, Cr, Fe, Co, Ni, Cu, Ga, Mn, Cu, Sr, W, Cd, Mo, Ru, Pd, Ir, Ta, Nb, Cs, Ba, La, Ce, or Fe, but the inventive concept is not limited to the examples set forth above.

In the photoresist composition according to some embodiments, the at least one N,O-β-heteroarylalkenolate ligand, which is included in the organometallic complex and includes an oxygen atom and a nitrogen atom each directly bonded to the metal element, may include a bidentate ligand including two atoms capable of being coordinated to the metal element. The at least one N,O-β-heteroarylalkenolate ligand may include both an electron donating group and an electron withdrawing group. The term “electron donating group” used herein refers to a group in which an atom in a covalent bond strongly tends to give a shared electron to another neighboring atom, and the term “electron withdrawing group” used herein refers to a group in which an atom in a covalent bond strongly tends to draw a shared electron from another neighboring atom.

In the at least one N,O-β-heteroarylalkenolate ligand, the electron donating group may be bonded to a heteroaryl group. In the at least one N,O-β-heteroarylalkenolate ligand of the organometallic complex, because the electron donating group is bonded to a heteroaryl group, a strong coordination bond may be formed between the heteroaryl group of the at least one N,O-β-heteroarylalkenolate ligand and the metal element, and thus, the organometallic complex may provide a relatively strong metal-ligand bond. In addition, because the at least one N,O-β-heteroarylalkenolate ligand includes a bidentate ligand, even when one of the binding sites of the bidentate ligand is separated from the metal element, the other binding site, for example, a binding site of a nitrogen atom of the heteroaryl group, may maintain a binding state to the metal element, thereby maintaining a binding state between the metal element and the at least one N,O-β-heteroarylalkenolate ligand and helping the separated binding site to rebind to the metal element. As such, in the organometallic complex including a bidentate ligand functioning as an electron doner, bonding stability between the metal element and the at least one N,O-β-heteroarylalkenolate ligand may be secured, and thus, the storage stability of the organometallic complex may improve.

In the organometallic complex of the photoresist composition according to some embodiments, the at least one N,O-β-heteroarylalkenolate ligand from among the plurality of ligands may include a C1-C30 organic ligand having a pyridinyl group, an oxazolyl group, or a benzothiazolyl group.

In some embodiments, in the photoresist composition according to some embodiments, the organometallic complex may include two N,O-β-heteroarylalkenolate ligands and at least one monodentate ligand. Each of the two N,O-β-heteroarylalkenolate ligands may have an oxygen atom and a nitrogen atom, which are each directly bonded to the metal element. The at least one monodentate ligand may include a C1-C20 hydrocarbon group directly bonded to the metal element. In some embodiments, the organometallic complex may include two monodentate ligands.

The organometallic complex of the photoresist composition according to some embodiments may be configured to have a structural change (e.g., capable of changing structure) in response to exposure to light. In some embodiments, in the photoresist composition according to some embodiments, the organometallic complex may be configured (e.g., capable) such that the monodentate ligand of the organometallic complex is dissociated from the metal element in response to exposure to light when the organometallic complex is exposed to light, e.g., light having a wavelength of about 10-250 nm, e.g., one selected from a KrF excimer laser (248 nm), an ArF excimer laser (193 nm), an F₂ excimer laser (157 nm), and an extreme ultraviolet (EUV) wavelength (13.5 nm).

In some embodiments, the organometallic complex may be represented by Formula 1.

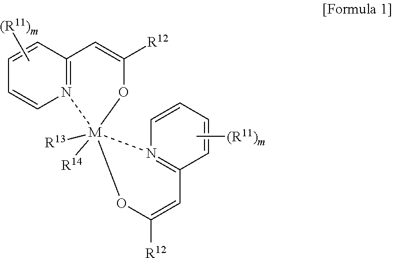

wherein, in Formula 1,
M is Sn, Sb, In, Bi, Ag, Te, Au, Pb, Zn, Ti, Hf, Zr, Al, V, Cr, Fe, Co, Ni, Cu, Ga, Mn, Cu, Sr, W, Cd, Mo, Ru, Pd, Ir, Ta, Nb, Cs, Ba, La, Ce, or Fe,
R¹¹ is a hydrogen atom, a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, a C2-C20 heteroaryl group, —Si(R^{a})(R^{b})(R^{c}) (wherein each of R^{a}, R^{b}, and R^{c} is the same or different and is a C1-C6 alkyl group), or an amino group,
R¹² is a halogen element, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, a C6-C20 aralkyl group substituted with a fluorine atom or a fluoroalkyl group, a carboxylic acid group (—COOH), an aldehyde group (—CHO), an ester group (—COOR^{f}), a ketone group (—COR^{f}), a sulfone group (—SOOR^{f}), an amide group (—CONH₂), a cyano group (—CN), a sulfonate group (—SO₃H), or a nitro group (—NO₂), and here, R^{f} is a C1-C20 alkyl group substituted with a fluorine atom or a fluoroalkyl group,
R¹³ and R¹⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and m is an integer of 1 to 4.

In some embodiments, in Formula 1, R¹¹ may be an electron donating group and R¹² may be an electron withdrawing group. In this case, R¹¹ is a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and R¹² is the same as defined above.

Herein, a hydrocarbon group refers to a group including a carbon atom and a hydrogen atom. Hydrocarbon groups include alkyl groups, alkenyl groups, alkynyl groups, aryl groups, aralkyl group, and alkylaryl groups, and each hydrocarbon group may include at least one hetero group in addition to a carbon atom and a hydrogen atom. The hetero group may include, but is not limited to, a halogen element (for example, fluorine, chlorine, bromine, or iodine), an amino group, an amido group, an alkoxy group, a carbonyl group, a carboxyl group, a mercapto group, an alkylmercapto group, a nitrile group, a nitro group, a sulfoxy group, or a sulfonyl group.

Herein, an alkyl group is a functional group derived from a linear or branched saturated hydrocarbon. Examples of the alkyl group may include, but are not limited to, a methyl group, an ethyl group, an n-propyl group, an isopropyl group, an n-butyl group, a sec-butyl group, a tert-butyl group, an n-pentyl group, a 1,1-dimethylpropyl group, a 1,2-dimethylpropyl group, a 2,2-dimethylpropyl group, a 1-ethylpropyl group, a 2-ethylpropyl group, an n-hexyl group, a 1-methyl-2-ethylpropyl group, a 1-ethyl-2-methylpropyl group, a 1,1,2-trimethylpropyl group, a 1-propylpropyl group, a 1-methylbutyl group, a 2-methylbutyl group, a 1,1-dimethylbutyl group, a 1,2-dimethylbutyl group, a 2,2-dimethylbutyl group, a 1,3-dimethylbutyl group, a 2,3-dimethylbutyl group, a 2-ethylbutyl group, a 2-methylpentyl group, a 3-methylpentyl group, and the like.

Herein, an alkenyl group is a radical of hydrogen and carbon, which has at least one double bond. Herein, the alkenyl group may be of a linear or branched type, unless otherwise defined. Examples of the alkenyl group may include, but are not limited to, an ethenyl group, a 1-propenyl group, a 2-propenyl group, a butenyl group, a pentenyl group, and the like.

Herein, an alkynyl group is a radical of hydrogen and carbon, which has at least one carbon-carbon triple bond. Herein, the alkynyl group may be of a linear or branched type, unless otherwise defined. Examples of the alkynyl group may include, but are not limited to, an ethynyl group, a 1-propynyl group, a 2-propynyl group, a butynyl group, a pentynyl group, and the like.

Herein, examples of the cycloalkyl group may include, but are not limited to, a cyclopropyl group, a cyclobutyl group, a cyclopentyl group, a cyclohexyl group, and the like.

Herein, examples of the alkoxy group may include, but are not limited to, a methoxy group, an ethoxy group, an n-propyloxy group, an isopropyloxy group, a butoxy group, a pentoxy group, and the like.

Herein, a halogen element refers to fluorine, chlorine, bromine, or iodine.

Herein, an aryl group is a monovalent substituent derived from an aromatic hydrocarbon. Examples of the aryl group may include, but are not limited to, a phenyl group, a naphthyl group, an anthracenyl group, a phenanathryl group, a naphthacenyl group, a pyrenyl group, a tolyl group, a biphenylyl group, a terphenylyl group, a chrycenyl group, a spirobifluorenyl group, a fluoranthenyl group, a fluorenyl group, a perylenyl group, an indenyl group, an azulenyl group, a heptalenyl group, a phenalenyl group, a phenanthrenyl group, and the like.

Herein, a heteroaryl group is an aromatic heterocyclic group derived from a monocyclic or condensed-cyclic compound. The heteroaryl group may include, as a heteroatom, at least one of nitrogen (N), sulfur(S), oxygen (O), phosphorus (P), selenium (Se), and silicon (Si). Examples of the heteroaryl group may include, but are not limited to, nitrogen-containing heteroaryl groups including a pyrrolyl group, a pyridyl group, a pyridazinyl group, a pyrimidinyl group, a pyrazinyl group, a triazolyl group, a tetrazolyl group, a benzotriazolyl group, a pyrazolyl group, an imidazolyl group, a benzimidazolyl group, an indolyl group, an isoindolyl group, an indolizinyl group, a purinyl group, an indazolyl group, a quinolyl group, an isoquinolinyl group, a quinolizinyl group, a phthalazinyl group, a naphthylidinyl group, a quinoxalinyl group, a quinazolinyl group, a cinnolinyl group, a pteridinyl group, an imidazotriazinyl group, a pyrazinopyridazinyl group, an acridinyl group, a phenanthridinyl group, a carbazolyl group, a carbazolinyl group, a pyrimidinyl group, a phenanthrolinyl group, a phenazinyl group, an imidazopyridinyl group, an imidazopyrimidinyl group, a pyrazolopyridinyl group, a pyrazolopyridinyl group, and the like; sulfur-containing heteroaryl groups including a thienyl group, a benzothienyl group, a dibenzothienyl group, and the like; oxygen-containing heteroaryl groups including a furyl group, a pyranyl group, a cyclopentapyranyl group, a benzofuranyl group, an isobenzofuranyl group, a dibenzofuranyl group, and the like; and compounds including at least two heteroatoms, such as a thiazolyl group, an isothiazolyl group, a benzothiazolyl group, a benzothiadiazolyl group, a phenothiazinyl group, an isoxazolyl group, a furazanyl group, a phenoxazinyl group, an oxazolyl group, a benzoxazolyl group, an oxadiazolyl group, a pyrazolooxazolyl group, an imidazothiazolyl group, a thienofuranyl group, a furopyrrolyl group, a pyridoxazinyl group, and the like.

Herein, an aralkyl group is a radical in which an aryl group is bonded to an alkyl group, and examples of the aralkyl group may include, but are not limited to, a benzyl group, a phenethyl group, a pyridylmethyl group, and the like.

In some embodiments, the organometallic complex may be represented by Formula 2.

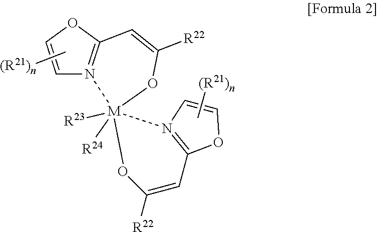

wherein, in Formula 2,
M is Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Ta, Nb, Cs, Ba, La, Ce, or Fe,
R²¹ is a hydrogen atom, a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group,
R²² is a fluorine atom, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, or a C6-C20 aralkyl group substituted with a fluorine atom or a fluoroalkyl group,
R²³ and R²⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and
n is 1 or 2.

In some embodiments, in Formula 2, R²¹ may be an electron donating group and R²² may be an electron withdrawing group. In this case, R²¹ is a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and R²² is the same as defined above.

In some embodiments, the organometallic complex may be represented by Formula 3.

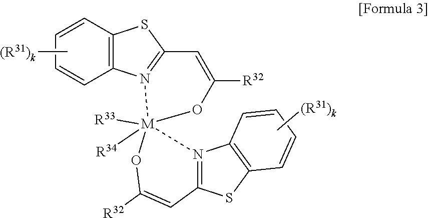

wherein, in Formula 3,
M is Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Ta, Nb, Cs, Ba, La, Ce, or Fe,
R³¹ is a hydrogen atom, a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group,
R³² is a fluorine atom, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, or a C6-C20 aralkyl group substituted with a fluorine atom or a fluoroalkyl group,
R³³ and R³⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and k is an integer of 1 to 4.

In some embodiments, in Formula 3, R³¹ may be an electron donating group and R³² may be an electron withdrawing group. In this case, R³¹ is a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and R³² is the same as defined above.

In some embodiments, the organometallic complex may be represented by Formula 4.

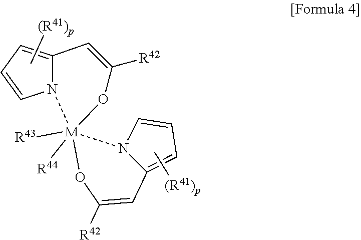

wherein, in Formula 4,
M is Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Ta, Nb, Cs, Ba, La, Ce, or Fe,
R⁴¹ is a hydrogen atom, a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group,
R⁴² is a fluorine atom, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, or a C6-C20 aralkyl group substituted with a fluorine atom or a fluoroalkyl group,
R⁴³ and R⁴⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and
p is an integer of 1 to 3.

In some embodiments, in Formula 4, R⁴¹ may be an electron donating group and R⁴² may be an electron withdrawing group. In this case, R⁴¹ is a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and R⁴² is the same as defined above.

In some embodiments, the organometallic complex may be represented by one selected from Formulae 1-1, 1-2, 1-3, 1-4, 1-5, 1-6, 1-7, and 1-8.

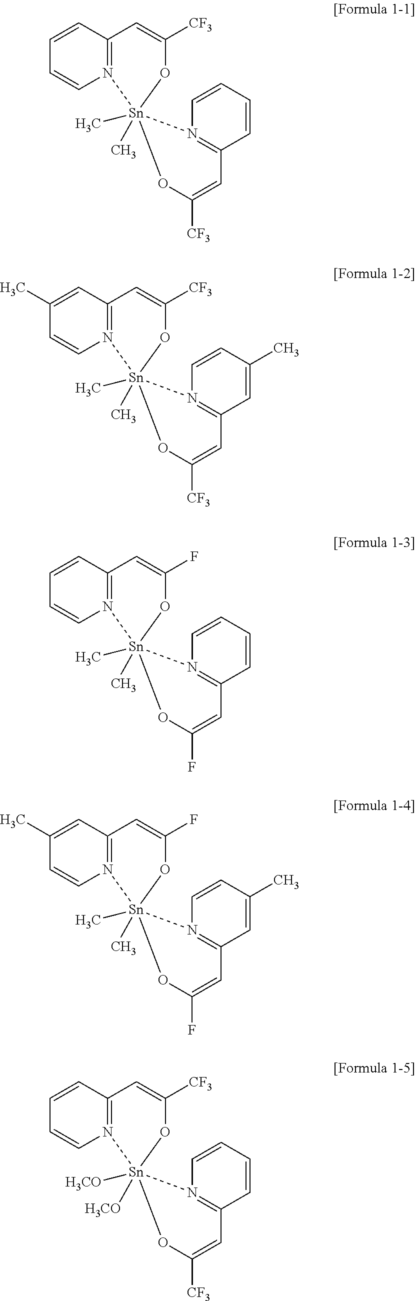

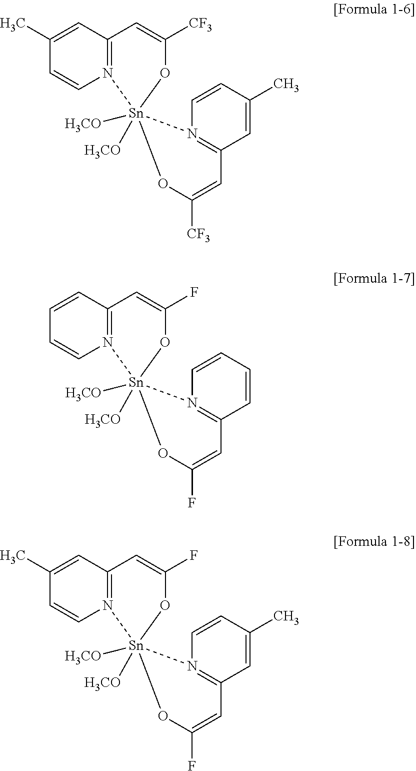

In some embodiments, the organometallic complex may be represented by one selected from Formulae 2-1, 2-2, 2-3, 2-4, 2-5, 2-6, 2-7, and 2-8.

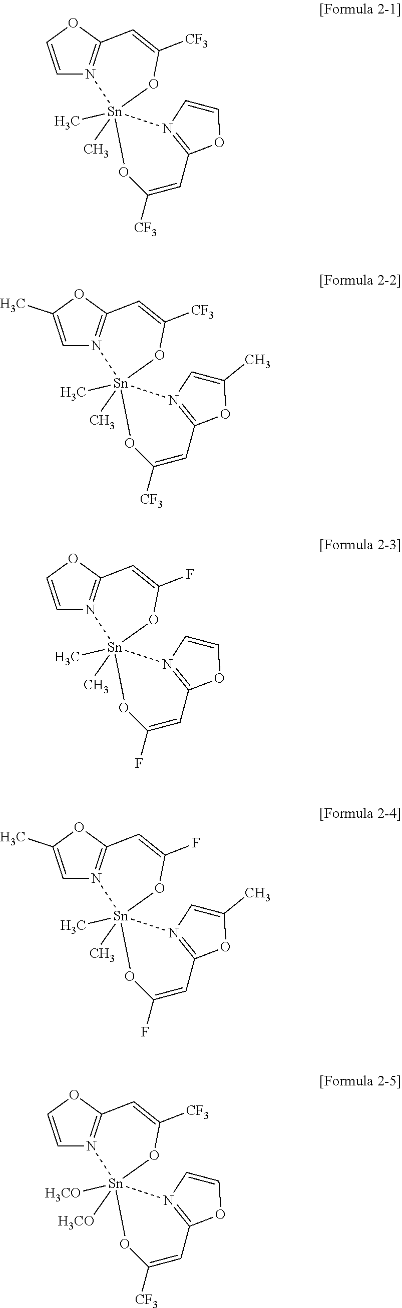

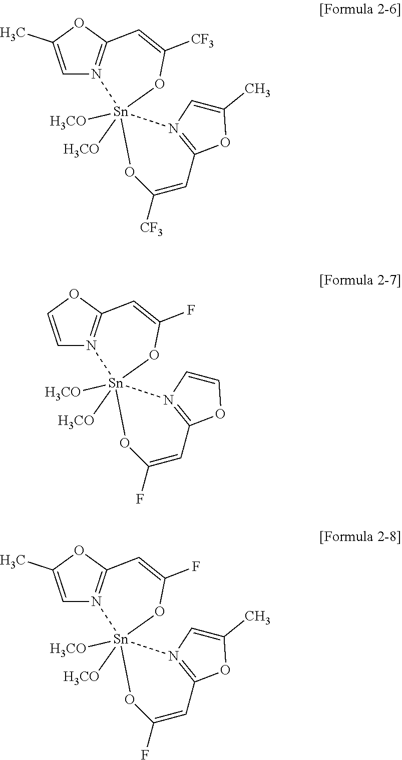

In some embodiments, the organometallic complex may be represented by one selected from Formulae 3-1, 3-2, 3-3, 3-4, 3-5, 3-6, 3-7, and 3-8.

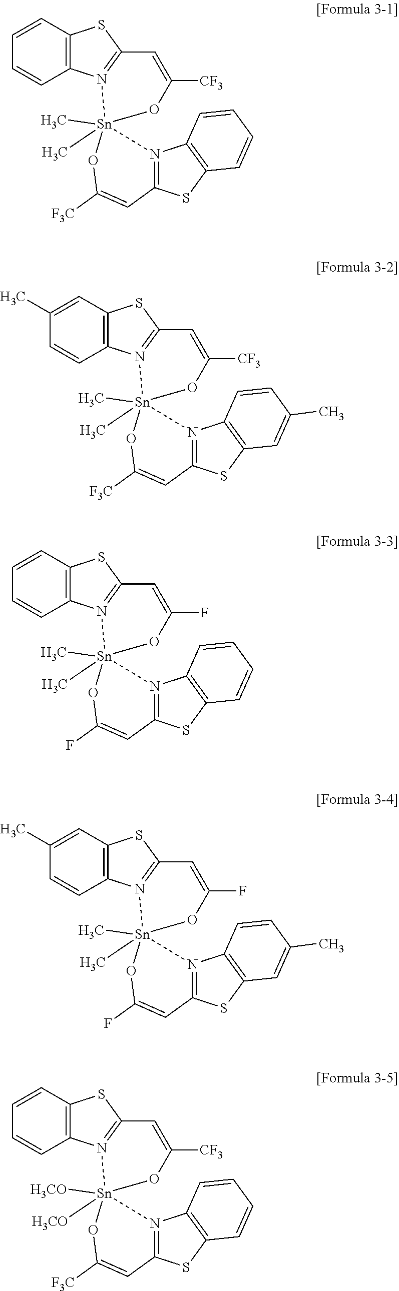

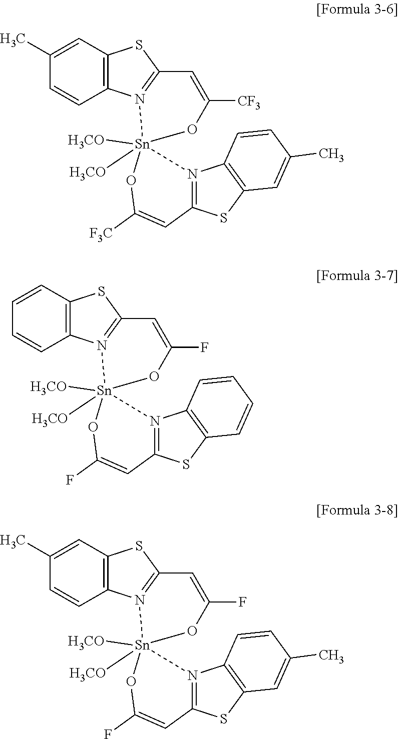

In some embodiments, the organometallic complex may be represented by one selected from Formulae 4-1, 4-2, 4-3, 4-4, 4-5, 4-6, 4-7, and 4-8.

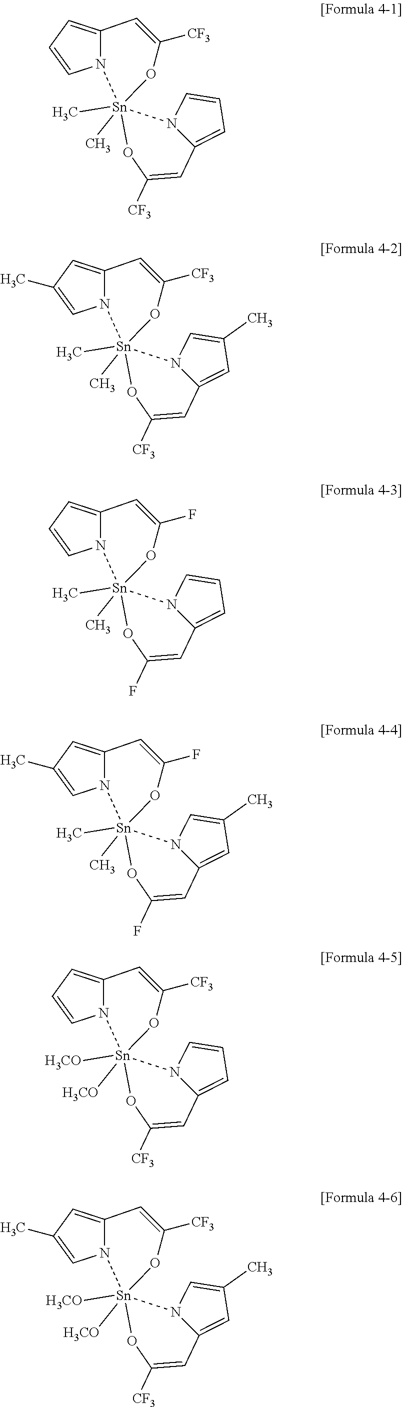

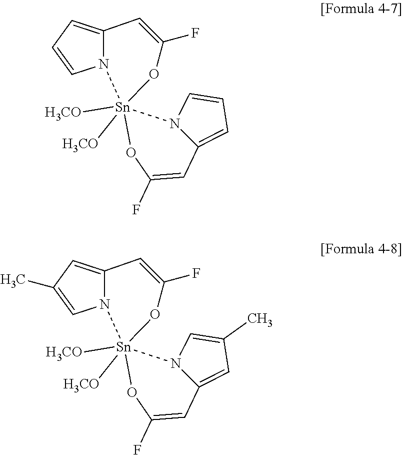

However, the organometallic complex, which may be included in the photoresist composition according to the inventive concept, is not limited to the examples set forth above and may be variously modified and changed without departing from the scope of the inventive concept.

In the photoresist composition according to some embodiments, the organometallic complex may be present in an amount of about 50 wt % to about 95 wt % based on the total weight of the photoresist composition, or any range therein, but the inventive concept is not limited thereto. In the photoresist composition according to some embodiments, the metal element may be present in an amount of about 0.1 wt % to about 5 wt % based on the total weight of the photoresist composition, or any range therein, but the inventive concept is not limited thereto.

The organometallic complex, which is included in the photoresist composition according to some embodiments, may be commercially available or may be obtained from a well-known precursor through synthesis by using a method publicly known to those of ordinary skill in the art. For example, when the organometallic complex has a structure of Formula 1-5, to synthesize the organometallic complex, first, tin(VI) t-butoxide (Sn(OtBu)₄) may react with 3,3,3-trifluoro (pyridin-2-yl) propen-2-ol (PyTFPH) in an aprotic solvent, for example, N,N-dimethylformamide (DMF), and then, a material remaining after the aprotic solvent and volatile materials are removed may be crystallized by using tetrahydrofuran (THF), thereby obtaining the organometallic complex. In another example, when the organometallic complex has a structure of Formula 2-5, to synthesize the organometallic complex, first, tin(VI) t-butoxide (Sn(OtBu)₄) may react with 3,3,3-trifluoro (dimethyl-1,3-oxazol-2-yl) propen-2-ol (DMOTFPH) in an aprotic solvent, for example, DMF, and then, a material remaining after the aprotic solvent and volatile materials are removed may be crystallized by using THE, thereby obtaining the organometallic complex. In yet another example, when the organometallic complex has a structure of Formula 3-5, to synthesize the organometallic complex, first, tin(VI) t-butoxide (Sn(OtBu)₄) may react with 3,3,3-trifluoro (1,3-benzothiazol-2-yl) propen-2-ol (BTTFPH) in an aprotic solvent, for example, DMF, and then, a material remaining after the aprotic solvent and volatile materials are removed may be crystallized by using THF, thereby obtaining the organometallic complex. In yet another example, when the organometallic complex has a structure of Formula 4-5, to synthesize the organometallic complex, first, tin(VI) t-butoxide (Sn(OtBu)₄) may react with 3,3,3-trifluoro-2-(1H-pyrrol-2-yl) propan-1-ol in an aprotic solvent, for example, DMF, and then, a material remaining after the aprotic solvent and volatile materials are removed may be crystallized by using THE, thereby obtaining the organometallic complex.

The solvent, which is included in the photoresist composition according to some embodiments, may include a nonpolar organic solvent. The nonpolar organic solvent may include, but is not limited to, a hydrocarbon compound, such as pentane, pentene, cyclopentane, hexane, cyclohexane, hexene, heptane, cycloheptane, octane, nonane, decane, undecane, dodecane, benzene, toluene, or the like; 1,4-dioxan; chloroform (CHCl₃); diethyl ether; carbon tetrachloride (CCl₄); or a combination thereof.

In the photoresist composition according to some embodiments, the solvent may be present in the balance amount except for amounts of main components including the organometallic complex. In some embodiments, the solvent may be present in an amount of about 5 wt % to about 50 wt % based on the total weight of the photoresist composition, or any range therein, but the inventive concept is not limited thereto.

When the photoresist composition according to some embodiments is exposed to light, a dissociation reaction of some ligands from among a plurality of organic ligands of the organometallic complex may occur in a light-exposed area of a photoresist film. For example, when the organometallic complex has a structure of Formula 1, R¹³ and R¹⁴, which are respectively monodentate ligands from among the plurality of organic ligands of the organometallic complex, may be dissociated from the organometallic complex. In another example, when the organometallic complex has a structure of Formula 2, R²³ and R²⁴, which are respectively monodentate ligands from among the plurality of organic ligands of the organometallic complex, may be dissociated from the organometallic complex. In yet another example, when the organometallic complex has a structure of Formula 3, R³³ and R³⁴, which are respectively monodentate ligands from among the plurality of organic ligands of the organometallic complex, may be dissociated from the organometallic complex. After the organic ligands (for example, R¹³ and R¹⁴ in Formula 1, R²³ and R²⁴ in Formula 2, or R³³ and R³⁴ in Formula 3) are dissociated, a hydroxyl (—OH) functional group may be generated at each of the sites from which the organic ligands are dissociated in the organometallic complex. In such a condition, a condensation reaction of the hydroxyl (—OH) functional group may be induced, and as a result, a network including a cross-linked structure (for example, an organometallic structure including an M-O-M cross-link) including a plurality of metals M may be densely formed.

The photoresist composition according to some embodiments may further include a photoinitiator including at least one selected from a photoacid generator (PAG) and a photoradical generator (PRG). The PAG may be configured to generate (e.g., capable of generating) an acid in response to light. The PRG may be configured to generate (e.g., capable of generating) a radical in response to light.

After a photoresist film obtained from the photoresist composition according to some embodiments is exposed to light, the photoinitiator may generate an acid or a radical by absorbing light in a light-exposed area of the photoresist film. When the photoresist film obtained from the photoresist composition is exposed to light, the acid or the radical generated from the photoinitiator may supplement the reactivity of the organometallic complex even in the case where the organometallic complex has relatively low reactivity, and the photosensitivity in the light-exposed area of the photoresist film may be adjusted by the amount of the photoinitiator.

The organometallic complex, which is included in the photoresist composition according to some embodiments, may be configured not to undergo breaking of the metal-ligand bond in response to light, e.g., capable of maintaining the metal-ligand bond when exposed to light. Therefore, because the organometallic complex has extremely low reactivity in a non-light-exposed area of the photoresist film obtained from the photoresist composition, an unintended dissociation reaction of the organometallic complex may be minimized. In the light-exposed area of the photoresist film obtained from the photoresist composition, some of the plurality of organic ligands of the organometallic complex may undergo a dissociation reaction. Here, even when some ligands of the organometallic complex in the light-exposed area have relatively low dissociation reactivity, the acid or the radical generated from the photoinitiator may accelerate a dissociation reaction of the ligands (for example, R¹³ and R¹⁴ in Formula 1, R²³ and R²⁴ in Formula 2, or R³³ and R³⁴ in Formula 3) of the organometallic complex, thereby inducing a photoreaction to restrictively occur only in the light-exposed area of the photoresist film.

The PAG may generate an acid when exposed to light, e.g., light having a wavelength of about 10-250 nm, e.g., one selected from a KrF excimer laser (248 nm), an ArF excimer laser (193 nm), an F₂ excimer laser (157 nm), and an EUV wavelength (13.5 nm). In some embodiments, the PAG may include triarylsulfonium salts, diaryliodonium salts, sulfonates, or mixtures thereof. For example, the PAG may include, but is not limited to, triphenylsulfonium triflate, triphenylsulfonium antimonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyldiphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

When the PRG is exposed to light, e.g., light having a wavelength of about 10-250 nm, e.g., one selected from a KrF excimer laser (248 nm), an ArF excimer laser (193 nm), an F₂ excimer laser (157 nm), and an EUV wavelength (13.5 nm), the PRG may absorb the light and generate a radical, thereby starting the polymerization of the organometallic complex of the photoresist composition according to some embodiments. In some embodiments, the PRG may include an acylphosphine oxide-based compound, an oxime ester-based compound, or the like.

The acylphosphine oxide-based compound may include, for example, 2,4,6-trimethylbenzoyl-diphenylphosphine oxide, bis(2,4,6-trimethylbenzoyl)-phenylphosphine oxide, bis(2,6-dimethoxybenzoyl)-(2,4,4-trimethylpentyl)phosphine oxide, or the like.

The oxime ester-based compound may include, for example, 1-phenylpropane-1,2-dione-2-(O-ethoxycarbonyl) oxime, 1-phenylbutane-1,2-dione-2-(O-methoxycarbonyl) oxime, 1,3-diphenylpropane-1,2,3-trione-2-(O-ethoxycarbonyl) oxime, 1-[4-(phenylthio)phenyl]octane-1,2-dione-2-(O-benzoyl) oxime, 1-[4-[4-(carboxyphenyl)thio]phenyl]propane-1,2-dione-2-(O-acetyl) oxime, 1-[9-ethyl-6-(2-methylbenzoyl)-9H-carbazol-3-yl]ethanone-1-(O-acetyl) oxime, 1-[9-ethyl-6-[2-methyl-4-[1-(2,2-dimethyl-1,3-dioxolane-4-yl)methyloxy]benzoyl]-9H-carbazol-3-yl] ethanone-1-(O-acetyl) oxime), or the like.

In some embodiments, the PRG may include a commercially available product, such as IRGACURE 651, IRGACURE 184, IRGACURE 1173, IRGACURE 2959, IRGACURE 127, IRGACURE 907, IRGACURE 369, IRGACURE 379, IRGACURE TPO, IRGACURE 819, IRGACURE OXE01, IRGACURE OXE02, IRGACURE MBF, or IRGACURE 754 (which is a product model of BASF Co., Ltd.).

The photoresist composition according to the inventive concept may include, as the photoinitiator, a single material selected from the PAGs and the PRGs set forth above, or may include, as the photoinitiator, at least two materials selected from the PAGs and the PRGs set forth above. In some embodiments, when the photoresist composition according to some embodiments includes the photoinitiator, the photoinitiator may be present in an amount of about 2 mol % to about 60 mol % based on the total amount of the organometallic complex, but the inventive concept is not limited thereto.

In some embodiments, when the photoresist composition according to some embodiments includes the PAG as the photoinitiator, the photoresist composition may further include a basic quencher. The basic quencher may include a compound capable of trapping an acid in the non-light-exposed area of the photoresist film, when the acid generated from the PAG or the acid generated from another photo-decomposable compound diffuses into the non-light-exposed area. The photoresist composition according to some embodiments includes the basic quencher, thereby suppressing, e.g., minimizing, the diffusion rate of an acid in the photoresist film obtained from the photoresist composition.

In some embodiments, the basic quencher may include primary aliphatic amines, secondary aliphatic amines, tertiary aliphatic amines, aromatic amines, heteroaromatic ring-containing amines, nitrogen-containing compounds having carboxyl groups, nitrogen-containing compounds having sulfonyl groups, nitrogen-containing compounds having hydroxyl groups, nitrogen-containing compounds having hydroxyphenyl groups, alcoholic nitrogen-containing compounds, amides, imides, carbamates, or ammonium salts. For example, the basic quencher may include, but is not limited to, triethanol amine, triethyl amine, tributyl amine, tripropyl amine, hexamethyl disilazan, aniline, N-methylaniline, N-ethylaniline, N-propylaniline, N,N-dimethylaniline, N,N-bis(hydroxyethyl) aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyltoluidine, or a combination thereof.

In some embodiments, the basic quencher may include a photobase generator. The photobase generator may generate a base by absorbing active energy rays through light irradiation and thus undergoing the decomposition of a chemical structure thereof. Accordingly, when a certain area of the photoresist film formed from the photoresist composition, which includes the basic quencher including the photobase generator, is exposed to light, the sensitivity in the light-exposed area may be adjusted by trapping an acid by the photobase generator in the light-exposed area of the photoresist film, and an acid may be suppressed from diffusing from the light-exposed area into a non-light-exposed area. Therefore, an organometallic structure network, which includes a metal oxide including the metal element, may be selectively formed only in the light-exposed area of the photoresist film. In some embodiment, the adverse effects due to the unintended diffusion of the acid, such as a deterioration in distributions of a critical dimension (CD) and line-edge roughness (LER) in an edge of a photoresist pattern obtained after a development process, may be minimized or prevented.

A material constituting the photobase generator is not particularly limited so long as the material generates a base in response to light irradiation. In some embodiments, the photobase generator may include a nonionic photobase generator. In some embodiments, the photobase generator may include an ionic photobase generator.

In some embodiments, the photobase generator may include a carboxylate or sulfonate salt of a photo-decomposable cation. For example, the photo-decomposable cation of the photobase generator may include a sulfonium cation. The sulfonium cation may include a substituted or unsubstituted C1-C12 alkyl group, a substituted or unsubstituted C3-C12 cycloalkyl group, a C6-C30 aryl group, or a C2-C30 heteroaryl group. The alkyl group, the cycloalkyl group, the aryl group, and the heteroaryl group may each include at least one heteroatom selected from an O atom, an S atom, and an N atom. For example, the sulfonium cation may include, but is not limited to, a phenyl group, a cyclopentyl group, a cyclohexyl group, an adamantyl group, a methyl group, an ethyl group, a propyl group, a butyl group, a t-butyl group, or an isopropyl group.

The photo-decomposable cation of the photobase generator may form a complex in company with an anion of a C1-C20 carboxylic acid. The carboxylic acid may include, but is not limited to, formic acid, acetic acid, propionic acid, tartaric acid, succinic acid, cyclohexanecarboxylic acid, benzoic acid, or salicylic acid.

In some embodiments, the photobase generator may include, but is not limited to, triphenylsulfonium heptafluorobutyric acid or triphenylsulfonium hexafluoroantimonate (TPS-SbF6).

In the photoresist composition according to the inventive concept, the basic quencher may be used alone, or a mixture of at least two basic quenchers may be used. The basic quencher may be present in an amount of about 0 mol % to about 50 mol % based on the total weight of the organometallic complex, but the inventive concept is not limited thereto.

In some embodiments, when the photoresist composition according to some embodiments includes the PRG as the photoinitiator, the photoresist composition may further include a radical quencher capable of trapping a radical.

In some embodiments, the radical quencher may include a quinone-type free radical or a nitroxide (IUPAC name: aminoxyl) free radical.

The quinone-type free radical may include, but is not limited to, p-benzoquinone, hydroquinone (1,4-dihydroxybenzene), hydroquinone monomethyl ether (4-methoxyphenol), hydroquinone monophenyl ether, mono-t-butyl hydroquinone (MTBHQ), di-t-butyl hydroquinone, di-t-amyl hydroquinone, toluhydroquinone, p-benzoquinone dioxime, 2,6-dichloro-1,4-benzoquinone, 2,3,5,6-tetramethyl-1,4-benzoquinone, 2,5-dichloro-3,6-dihydroxy-p-benzoquinone, methyl-p-benzoquinone, 6-anilinoquinoline-5,8-quinone, pyrroloquinoline quinone, 2-allyl-6-methoxybenzo-1,4-quinone, or a combination thereof.

The nitroxide free radical may include, but is not limited to, di-tert-butyl nitroxide (DTBN), 2,2,6,6-tetramethyl-1-peperidine 1-oxyl (TEMPO), oxo TEMPO (4-oxo-2,2,6,6-tetramethyl-1-peperidine 1-oxyl), 1,1,3,3-tetraethylisoindolin-N-oxyl, N-tert-butyl-N-[1-(diethoxyphosphoryl)-2,2-dimethylpropyl]aminoxyl (SG1), (N-tert-butyl-N-(2-methyl-1-phenylpropyl)aminoxyl (TIPNO), or a combination thereof.

When a photolithography process is performed by using the photoresist composition according to the inventive concept, because a radical generated from the PRG in the light-exposed area of the photoresist film obtained from the photoresist composition is quenched by the radical quencher, the sensitivity in the light-exposed area may be adjusted and a radical introduced from the light-exposed area into a non-light-exposed area may be quenched by the radical quencher. Therefore, a network, which includes an organometallic structure including the metal element, may be selectively formed only in the light-exposed area, and adverse effects due to the unintended diffusion of the radical, such as a deterioration in CD distribution in an edge of a photoresist pattern obtained after a development process, may be minimized or prevented.

In the photoresist composition according to the inventive concept, the radical quencher may be used alone, or a mixture of at least two radical quenchers may be used. The radical quencher may be present in an amount of about 0 mol % to about 10 mol % based on the total weight of the organometallic complex, but the inventive concept is not limited thereto.

In some embodiments, the photoresist composition according to some embodiments may further include at least one selected from a leveling agent, a surfactant, a dispersant, a moisture absorbent, and a coupling agent.

The leveling agent is for improving coating flatness when the photoresist composition is coated on a substrate, and a commercially available leveling agent publicly known in the art may be used.

The surfactant may improve the coating uniformity and wettability of the photoresist composition. In some embodiments, the surfactant may include, but is not limited to, a sulfuric acid ester salt, a sulfonic acid salt, phosphoric acid ester, soap, an amine salt, a quaternary ammonium salt, polyethylene glycol, an alkylphenol ethylene oxide adduct, a polyhydric alcohol, a nitrogen-containing vinyl polymer, or a combination thereof. For example, the surfactant may include an alkylbenzene sulfonate, an alkyl pyridinium salt, polyethylene glycol, or a quaternary ammonium salt. When the photoresist composition includes the surfactant, the surfactant may be present in an amount of about 0.001 wt % to about 3 wt % based on the total weight of the photoresist composition, or any range therein.

The dispersant may cause the respective components constituting the photoresist composition to be uniformly dispersed in the photoresist composition. In some embodiments, the dispersant may include, but is not limited to, an epoxy resin, polyvinyl alcohol, polyvinyl butyral, polyvinylpyrrolidone, glucose, sodium dodecyl sulfate, sodium citrate, oleic acid, linoleic acid, or a combination thereof. When the photoresist composition includes the dispersant, the dispersant may be present in an amount of about 0.001 wt % to about 5 wt % based on the total weight of the photoresist composition, or any range therein.

The moisture absorbent may minimize or prevent adverse effects due to water in the photoresist composition. In some embodiments, the moisture absorbent may include, but is not limited to, polyoxyethylene nonylphenol ether, polyethylene glycol, polypropylene glycol, polyacrylamide, or a combination thereof. When the photoresist composition includes the moisture absorbent, the moisture absorbent may be present in an amount of about 0.001 wt % to about 10 wt % based on the total weight of the photoresist composition, or any range therein.

The coupling agent may improve adhesion to a lower film when the photoresist composition is coated on the lower film. In some embodiments, the coupling agent may include a silane coupling agent. The silane coupling agent may include, but is not limited to, vinyltrimethoxysilane, vinyltriethoxysilane, vinyltrichlorosilane, vinyltris(β-methoxyethoxy)silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyldiethoxysilane, or trimethoxy [3-(phenylamino)propyl]silane. When the photoresist composition includes the coupling agent, the coupling agent may be present in an amount of about 0.001 wt % to about 5 wt % based on the total weight of the photoresist composition, or any range therein.

The organometallic complex of the photoresist composition according to some embodiments may be configured to have a structural change (e.g., capable of changing structure) in response to exposure to light. For example, in the photoresist composition according to some embodiments, the organometallic complex may be configured such that, when the organometallic complex is exposed to light, e.g., light having a wavelength of about 10-250 nm, e.g., one selected from a KrF excimer laser (248 nm), an ArF excimer laser (193 nm), an F₂ excimer laser (157 nm), and an EUV wavelength (13.5 nm), some ligands (for example, R¹³ and R¹⁴ in Formula 1, R²³ and R²⁴ in Formula 2, or R³³ and R³⁴ in Formula 3) of the organometallic complex are dissociated from the metal element in response to the exposure to light. Accordingly, an organometallic structure network having a dense structure may be selectively formed only in a light-exposed area of a photoresist film obtained from the photoresist composition according to some embodiments, and no organometallic structure network may be formed in a non-light-exposed area of the photoresist film, e.g., the non-light-exposed area of the photoresist film is devoid of, or substantially devoid of, an organometallic structure network. In some embodiments, the difference in solubility between the light-exposed area and the non-light-exposed area of the photoresist film can be increased. In some embodiments, when an integrated circuit device is manufactured by using a photoresist composition as exemplified herein, excellent resolution and improved sensitivity can be provided in a photolithography process. In some embodiments of the photolithography process, a photoresist pattern including the organometallic structure network, which is formed in the light-exposed area of the photoresist film obtained from the photoresist composition, can have dense crystallinity and thus provide excellent etch resistance and resolution. In some embodiments, when a pattern required for an integrated circuit device is formed by using the photoresist pattern exemplified herein, a deterioration in the CD distribution of the pattern can be minimized or prevented, thereby improving the dimensional precision of the pattern formed.

In some embodiments, the photoresist composition according to the inventive concept can be advantageously used in forming a pattern having a relatively high aspect ratio. For example, the photoresist composition according to the inventive concept may be advantageously used in a photolithography process of forming a line pattern or a pillar pattern having a fine width selected from a range of about 5 nm to about 100 nm, or any range therein.

In general, attempts are being made to manufacture an integrated circuit device having a fine feature size, for example, a feature size of about 3 nm or less, through a photolithography process using an EUV wavelength (13.5 nm). However, to this end, it is necessary to develop a high-sensitivity photoresist material, which has relatively high sensitivity to an EUV wavelength (13.5 nm) and thus is capable of implementing an intended pattern even with a small amount of light. Chemically amplified photoresist materials developed so far may have a resolution limit when trying to form line-and-space patterns having a pitch of about 36 nm or less and may have a limit in improving the photosensitivity, resolution, and LER characteristics thereof all together due to material properties of components constituting chemically amplified photoresist materials.

Unlike existing chemically amplified photoresist materials, the photoresist composition according to some embodiments includes an organometallic complex as a main component and can facilitate improved photosensitivity, resolution, and LER properties thereof, all together. However, when exposed to light, inorganic photoresist materials developed so far form amorphous metal oxides based on Sn—O—Sn bonds omnidirectionally and randomly generated around central metals, for example, Sn atoms, and there is a limit in reducing amorphous metal oxides formed as such to a specific size or less due to a limit in the properties of the amorphous structures of the amorphous metal oxides.

The photoresist composition according to the inventive concept is proposed to solve the above issues in existing chemically amplified photoresist materials and/or inorganic photoresist materials developed so far, and an organometallic complex, which is included in the photoresist composition according to the inventive concept, includes a plurality of organometallic complexes, which each includes a metal element and a plurality of ligands bonded to the metal element and including at least two different ligands. In some embodiments, when a photoresist film obtained from the photoresist composition is exposed to light, one or more of the plurality of organic ligands in each of the plurality of organometallic complexes undergo a dissociation reaction, and as a result, an unshared electron pair of the metal element is exposed from the organometallic complex. In addition, bonded structures between the metal element having the unshared electron pair that is exposed and the at least one N,O-β-heteroarylalkenolate ligand are crystal-grown in the vertical direction with respect to a main surface of the photoresist film. In some embodiments, an organometallic structure network with directionality restricted to the vertical direction may be selectively formed only in a light-exposed area of the photoresist film and the reaction diffusion into a non-light-exposed area of the photoresist film may be minimized. Therefore, a photoresist pattern with improved LER can be formed, and because a crystalline structure may be formed in the photoresist pattern itself, pattern uniformity may be controlled to a scale corresponding to the molecular size of each of the plurality of organometallic complexes, for example, a scale of several angstroms (Å). In some embodiments, the LER and LWR of the photoresist pattern formed can be at an extremely low level.

In addition, in some embodiments, the photoresist composition according to some embodiments may include only the plurality of organometallic complexes and a solvent as main components. Therefore, after a photoresist film obtained from the photoresist composition according to some embodiments is exposed to light, a post-exposure bake process allowing a radical and/or an acid to additionally diffuse may be omitted. As a comparison example, in photolithography processes using existing chemically amplified photoresist materials and/or inorganic photoresist materials previously developed, a post-exposure bake (PEB) process for the reaction of unreacted radicals and/or acids in a light-exposed areas is essential. In photolithography processes using existing chemically amplified photoresist materials and/or inorganic photoresist materials previously developed, because such photoresist materials are affected by radicals and/or acids when undergoing a PEB process, amorphous structures are formed toward an increase in entropy, and thus, there is a drawback in terms of LER/LWR control. On the other hand, in a photolithography process using the photoresist composition according to some embodiments, a PEB process may be omitted providing an advantage in terms of LER/LWR control. Therefore, in some embodiments of the inventive concept, excellent resolution and improved sensitivity may be provided in a photolithography process, and a pattern obtained by the photolithography process avoids a deterioration in CD distribution and can also have minimized LER and LWR, thereby improving the dimensional precision of the formed pattern. In addition, excellent etch resistance and resolution may be provided in a photolithography process.

Next, an exemplary method of manufacturing an integrated circuit device by using the photoresist composition according to some example embodiments is described.

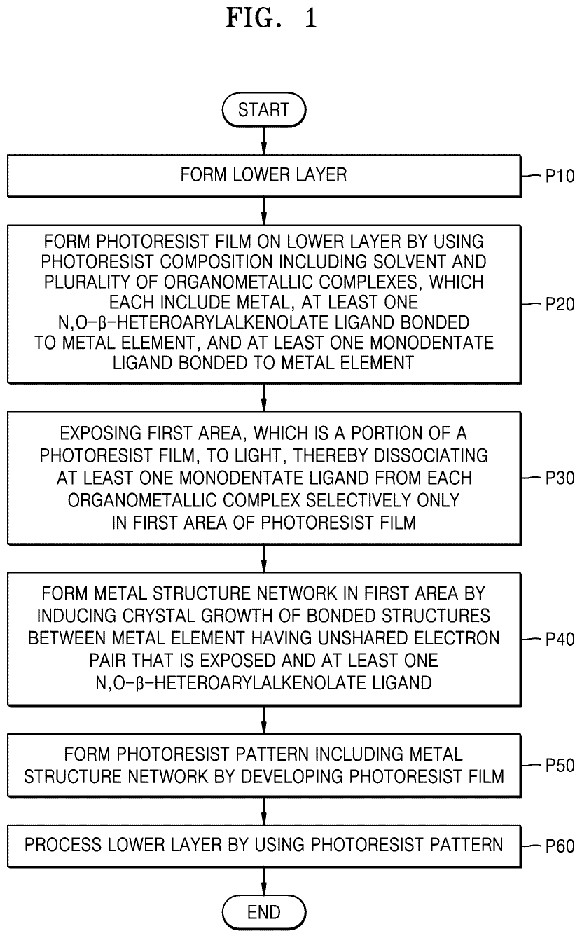

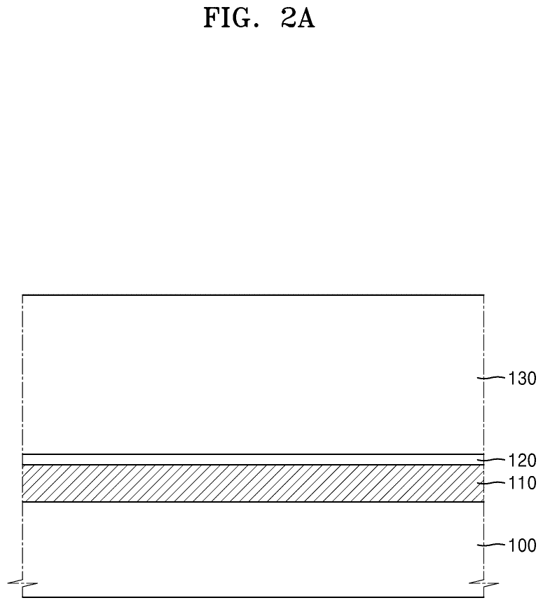

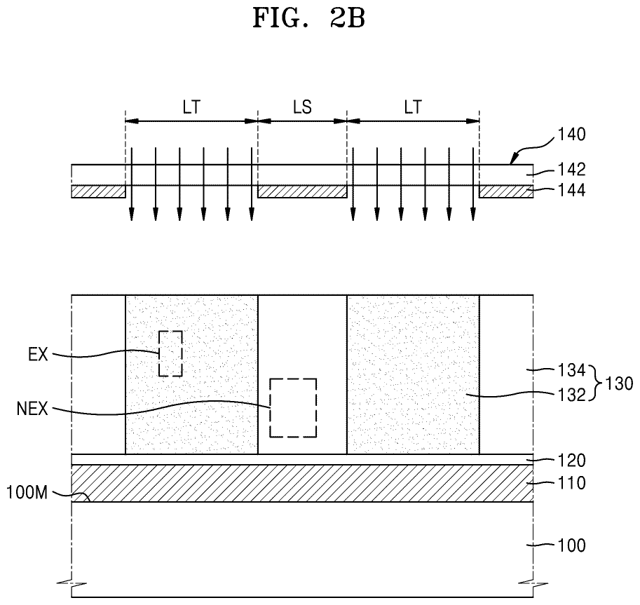

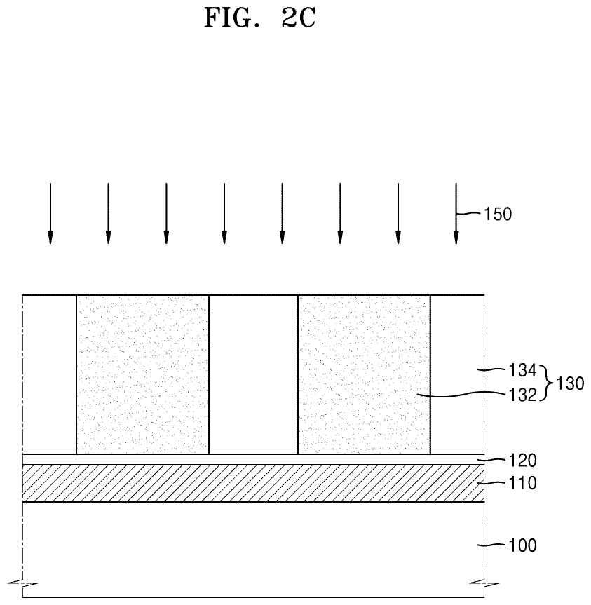

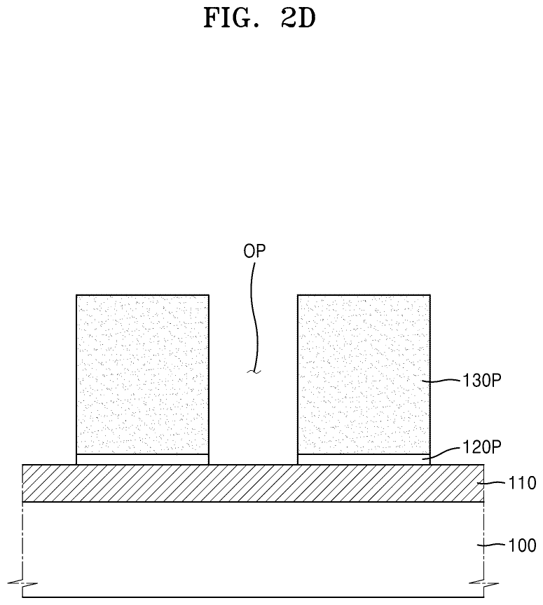

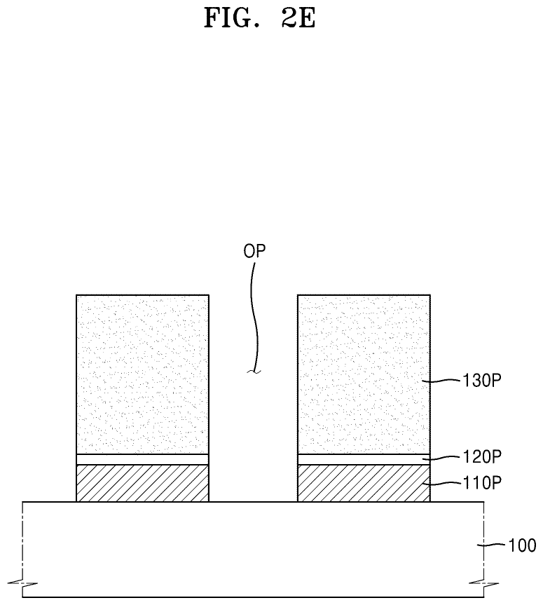

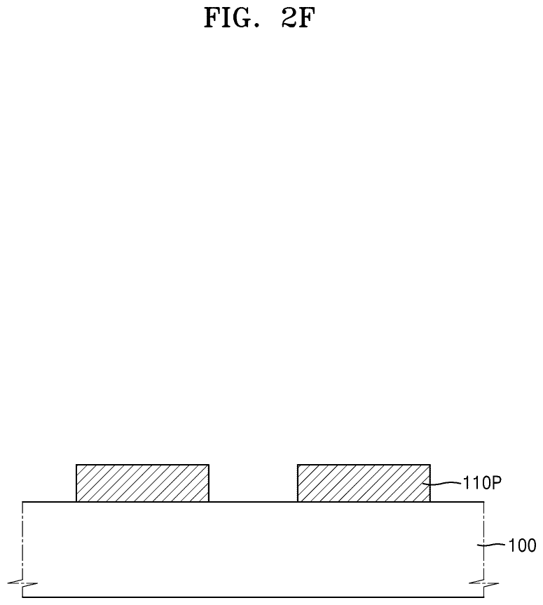

FIG. 1 is a flowchart illustrating a method of manufacturing an integrated circuit device, according to some embodiments. FIGS. 2A to 2F are cross-sectional views respectively illustrating a sequence of processes of a method of manufacturing an integrated circuit device, according to some embodiments.

Referring to FIGS. 1 and 2A, in process P10, a lower layer 110 may be formed on a substrate 100. Next, in process P20, a photoresist film 130 may be formed on the lower layer 110 by using the photoresist composition according to some embodiments. A more detailed configuration of the photoresist composition is the same as described above.

The substrate 100 may include a semiconductor substrate. The lower layer 110 may include an insulating film, a conductive film, or a semiconductor film. For example, the lower layer 110 may include, but is not limited to, a metal, an alloy, a metal carbide, a metal nitride, a metal oxynitride, a metal oxycarbide, a semiconductor, polysilicon, an oxide, a nitride, an oxynitride, or a combination thereof.

In some embodiments, as shown in FIG. 2A, before the photoresist film 130 is formed on the lower layer 110, a lower film 120 may be formed on the lower layer 110. In this case, the photoresist film 130 may be formed on the lower film 120. In some embodiments, the lower film 120 prevents the photoresist film 130 from being adversely affected by the lower layer 110 under the photoresist film 130. In some embodiments, the lower film 120 may include an organic or inorganic anti-reflective coating (ARC) material for KrF excimer lasers, ArF excimer lasers, EUV light, or any other light sources. In some embodiments, the lower film 120 may include a bottom anti-reflective coating (BARC) film or a developable bottom anti-reflective coating (DBARC) film. In some embodiments, the lower film 120 may include an organic component having a light absorption structure. The light absorption structure may include, for example, a hydrocarbon compound having a structure in which one or more benzene rings are fused. The lower film 120 may have, but is not limited to, a thickness of about 1 nm to about 100 nm. In some embodiments, the lower film 120 may be omitted.

To form the photoresist film 130, the photoresist composition according to some embodiments may be coated on the lower film 120 and then treated with heat. The coating may be performed by a method, such as spin coating, spray coating, dip coating, or the like. A process of heat-treating the photoresist composition may be performed at a temperature of about 80° C. to about 300° C. for about 10 seconds to about 100 seconds, or any range of temperature and time therein, but the inventive concept is not limited thereto. The thickness of the photoresist film 130 may be tens to hundreds of times the thickness of the lower film 120. The photoresist film 130 may have, but is not limited to, a thickness of about 10 nm to about 1 μm, or any range therein.

The photoresist composition according to some embodiments includes a plurality of organometallic complexes, which each include a metal element and a plurality of ligands bonded to the metal element and including at least two different ligands, and a solvent, and the plurality of ligands in each of the plurality of organometallic complexes include at least one N,O-β-heteroarylalkenolate ligand having an oxygen atom and a nitrogen atom, wherein the oxygen atom and the nitrogen atom are each directly bonded to the metal element, and at least one monodentate ligand bonded to the metal element. Because the at least one N,O-β-heteroarylalkenolate ligand in each of the plurality of organometallic complexes includes an oxygen atom and a nitrogen atom, which are each directly bonded to the metal element, and is a bidentate ligand including two atoms capable of being coordinated to the metal element, the at least one N,O-β-heteroarylalkenolate ligand may be suppressed from being dissociated from the metal element, and the bond between the metal element and the at least one N,O-β-heteroarylalkenolate ligand may be stably maintained while the photoresist film 130 is being formed or during the waiting time for a subsequent process after the formation of the photoresist film 130, even when the photoresist film 130 is exposed to water in the air.

Referring to FIGS. 1 and 2B, in process P30, a first area 132 that is a portion of the photoresist film 130 may be exposed to light, and thus, the at least one monodentate ligand bonded to the metal element in each of the plurality of organometallic complexes of the photoresist film 130 in the first area 132 may be dissociated from the plurality of organometallic complexes, thereby exposing an unshared electron pair of the metal element.

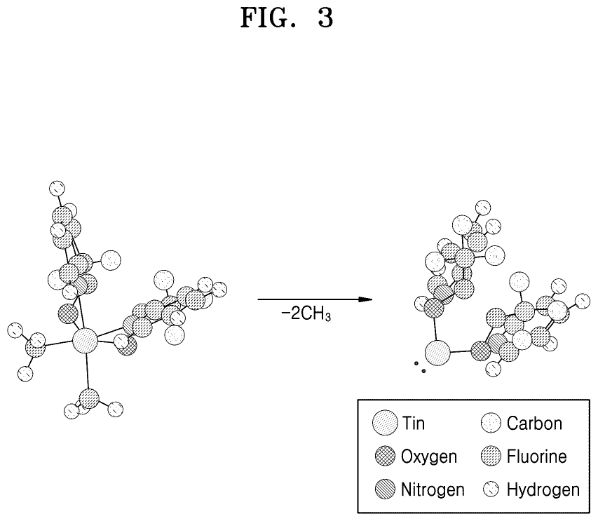

FIG. 3 is a diagram illustrating a structural change of the organometallic complex of the photoresist film 130 in the first area 132 before and after the first area 132 of the photoresist film 130 is exposed to light according to process P30 of FIG. 1.

FIG. 3 illustrates an example in which each of the plurality of organometallic complexes has a structure of Formula 1-1. Referring to FIG. 3, in the organometallic complex having the structure of Formula 1-1, Sn—C bond energy between tin (Sn) and two methyl groups that are monodentate ligands may be less than Sn—N bond energy and Sn—O bond energy between tin (Sn) and the N,O-β-heteroarylalkenolate ligand. Therefore, when the organometallic complex, which is included in the photoresist film 130 and has the structure of Formula 1-1, is exposed to light, the two methyl groups that are monodentate ligands may be dissociated from the organometallic complex, and an unshared electron pair of tin (Sn) that is included in the organometallic complex may be exposed.

In some embodiments, in the case where each of the plurality of organometallic complexes of the photoresist film 130 has a structure of Formula 1-5, similar to the description made with reference to FIG. 3, when the organometallic complex, which is included in the photoresist film 130 and has the structure of Formula 1-5, is exposed to light, two methoxy groups that are monodentate ligands may be dissociated from the organometallic complex, and an unshared electron pair of tin (Sn) that is included in the organometallic complex may be exposed.

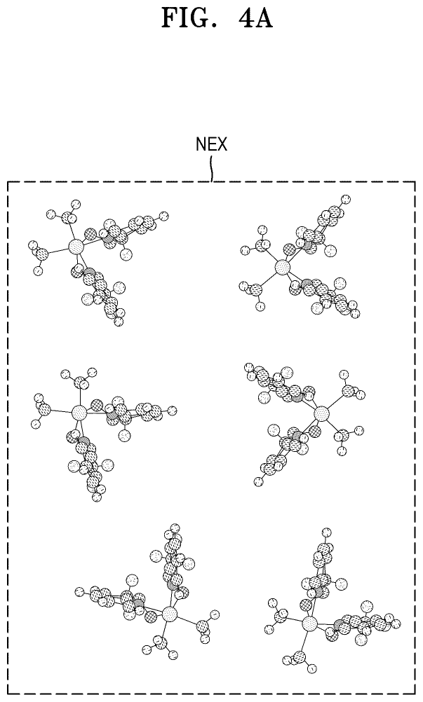

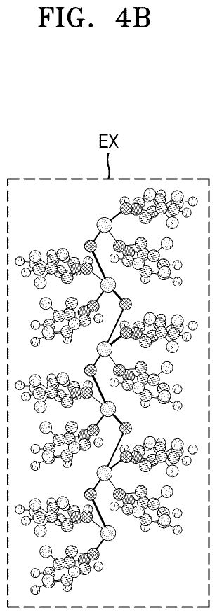

FIG. 4A is a diagram illustrating organometallic complexes in a region NEX in a second area 134 that is not exposed to light in FIG. 2B, and FIG. 4B is a diagram illustrating organometallic complexes in a region EX in the first area 132 that is exposed to light in FIG. 2B. FIGS. 4A and 4B illustrate an example in which each of the plurality of organometallic complexes has a structure of Formula 1-1.

Referring to FIGS. 1 and 2B, in process P40, the crystal growth of bonded structures between the metal element having an unshared electron pair that is exposed and the at least one N,O-β-heteroarylalkenolate ligand may be induced in the first area 132 exposed to light, thereby forming an organometallic structure network in the first area 132.

As shown in FIG. 4A, after the first area 132 of the photoresist film 130 is exposed to light according to process P30 of FIG. 1, the organometallic complexes of the photoresist film 130 in the second area 134 may have no structural change and may be dispersed in disorder. On the other hand, as shown in FIG. 4B, in the first area 132 exposed to light, two methyl groups that are monodentate ligands may be dissociated from each of the organometallic complexes of the photoresist film 130, and serial adsorption reactions may be stably performed by forming sequential Sn—O—Sn cross-links in the vertical direction (a direction perpendicular to a main surface, e.g., along a Z-axis, 100M of the substrate 100) by tin (Sn) of each of the organometallic complexes in company with adjacent tin (Sn), thereby forming a crystal structure. The crystal structure formed as such may perform no additional reaction with water due to the excellent stability thereof against water and oxygen and may have no additional change in material properties thereof because the reactivity of the crystal structure may be adjusted only by exposure to light.

Referring again to FIG. 2B, in the case where the photoresist composition according to some embodiments, which is used to form the photoresist film 130, further includes a photoinitiator including at least one selected from a PAG configured to generate an acid in response to light and a PRG configured to generate a radical in response to light, when the first area 132 that is a portion of the photoresist film 130 is exposed to light according to process P30 of FIG. 1, the photoinitiator of the photoresist film 130 in the first area 132 may absorb light and thus generate an acid and/or a radical. The acid and/or the radical generated from the photoinitiator may accelerate a reaction in which two methyl groups that are monodentate ligands are dissociated from each of the organometallic complexes of the photoresist film 130 in the first area 132 exposed to light.

As described with reference to FIG. 2B, after the first area 132 is exposed to light, the difference in solubility in a developer between the first area 132 and the second area 134 of the photoresist film 130 may be increased.

In some embodiments, to expose the first area 132 of the photoresist film 130 to light, a photomask 140, which has a plurality of light shielding areas LS and a plurality of light transmitting areas LT, may be aligned at a certain position over the photoresist film 130, and the first area 132 of the photoresist film 130 may be exposed to light through the plurality of light transmitting areas LT of the photomask 140. To expose the first area 132 of the photoresist film 130 to light, a KrF excimer laser (248 nm), an ArF excimer laser (193 nm), an F₂ excimer laser (157 nm), or an EUV wavelength (13.5 nm) may be used.

In some embodiments, the photomask 140 may include a transparent substrate 142, and a plurality of light shielding patterns 144 formed in the plurality of light shielding areas LS on the transparent substrate 142. The transparent substrate 142 may include quartz. The plurality of light shielding patterns 144 may include chromium (Cr). The plurality of light transmitting areas LT may be defined by the plurality of light shielding patterns 144. According to the inventive concept, to expose the first area 132 of the photoresist film 130 to light, a reflective photomask (not shown) for EUV exposure may be used instead of the photomask 140.

Referring to FIG. 2C, a bake process may be performed by applying heat 150 to the photoresist film 130 including the first area 132 that is exposed to light.

The bake process may be performed at a temperature of about 50° C. to about 400° C. for about 10 seconds to about 150 seconds. For example, the bake process may be performed at a temperature of about 150° C. to about 250° C. for about 60 seconds to about 120 seconds, but the inventive concept is not limited thereto.

In some embodiments, while the bake process of the photoresist film 130 is performed, an acid or a radical generated from the photoinitiator in the first area 132 may accelerate a reaction in which two methyl groups that are monodentate ligands are dissociated from each of the organometallic complexes of the photoresist film 130 in the first area 132 that is exposed to light. In some embodiments, the bake process of the photoresist film 130, which is described with reference to FIG. 2C, may be omitted.

Referring to FIGS. 1 and 2D, in process P50, the second area 134 of the photoresist film 130 may be removed by developing the photoresist film 130 by using a developer. In some embodiments, the development of the photoresist film 130 may be performed by a negative-tone development (NTD) process. As a result, a photoresist pattern 130P, which includes the organometallic structure network formed in the light-exposed first area 132 of the photoresist film 130, may be formed.

The photoresist pattern 130P may include a plurality of openings OP. After the photoresist pattern 130P is formed, a lower pattern 120P may be formed by removing portions of the lower film 120, which are exposed by the plurality of openings OP.

In some embodiments, to develop the photoresist film 130, a developer including an organic solvent may be used. For example, the developer may include, but is not limited to, ketones, such as methyl ethyl ketone, acetone, cyclohexanone, and 2-heptanone; alcohols, such as 4-methyl-2-propanol, 1-butanol, isopropanol, 1-propanol, and methanol; esters, such as propylene glycol monomethyl ether acetate, ethyl acetate, ethyl lactate, n-butyl acetate, and butyrolactone; aromatic compounds, such as benzene, xylene, and toluene; or combinations thereof. As described with reference to FIG. 2C, as the difference in solubility in the developer between the light-exposed first area 132 and the non-light-exposed second area 134 in the photoresist film 130 is increased, while the second area 134 is removed by developing the photoresist film 130 in the process of FIG. 2D, the first area 132 may remain as it is without being removed. Therefore, after the photoresist film 130 is developed, residual defects, such as a footing phenomenon, may not occur, and a vertical sidewall profile of the photoresist pattern 130P may be obtained. As such, by improving the sidewall profile of the photoresist pattern 130P, the CD of an intended processing region in the lower layer 110 may be precisely controlled when the lower layer 110 is processed by using the photoresist pattern 130P.

In some embodiments, after the photoresist pattern 130P is formed by developing the photoresist film 130, as described with reference to FIG. 2D, a process of performing hard bake on an obtained resulting product may be further performed. Through the hard bake process, unnecessary materials, such as the developer remaining on the resulting product in which the photoresist pattern 130P is formed, may be removed. Through the hard bake process, the hardness of the photoresist pattern 130P may be further increased.

The hard bake process may be performed at a temperature of about 50° C. to about 400° C. for about 10 seconds to about 150 seconds. For example, the hard bake process may be performed at a temperature of about 150° C. to about 250° C. for about 60 seconds to about 120 seconds, but the inventive concept is not limited thereto.

Referring to FIGS. 1 and 2E, in process P60, in the resulting product of FIG. 2D, the lower layer 110 may be processed by using the photoresist pattern 130P.

To process the lower layer 110, various processes, such as a process of etching the lower layer 110 exposed by an opening OP of the photoresist pattern 130P, a process of implanting impurity ions into the lower layer 110, a process of forming an additional film on the lower layer 110 through the opening OP, and a process of modifying a portion of the lower layer 110 through the opening OP, may be performed. Although FIG. 2E illustrates, as an example of a process of processing the lower layer 110, an example of forming a feature pattern 110P by etching the lower layer 110 exposed by the opening OP, the inventive concept is not limited thereto.

In some embodiments, the process of forming the lower layer 110 may be omitted from the process described with reference to FIG. 2A, and in this case, instead of the process P60 of FIG. 1 and the process described with reference to FIG. 2E, the substrate 100 may be processed by using the photoresist pattern 130P. For example, various processes, such as a process of etching a portion of the substrate 100 by using the photoresist pattern 130P, a process of implanting impurity ions into a portion of the substrate 100, a process of forming an additional film on the substrate 100 through the opening OP, and a process of modifying a portion of the substrate 100 through the opening OP, may be performed.

Referring to FIG. 2F, in the resulting product of FIG. 2E, the photoresist pattern 130P and the lower pattern 120P, which remain on the feature pattern 110P, may be removed, resulting in retention of the feature pattern 110P on the lower layer 110. To remove the photoresist pattern 130P and the lower pattern 120P, ashing and strip processes may be used.

According to the method of manufacturing an integrated circuit device, which is described with reference to FIGS. 1 and 2A to 2F, a difference in solubility in a developer between a light-exposed area and a non-light-exposed area of the photoresist film 130, which is obtained by using the photoresist composition according to the inventive concept, may be increased, and the CD distribution in the photoresist pattern 130P may improve. Therefore, when a subsequent process is performed on the lower layer 110 and/or the substrate 100 by using the photoresist pattern 130P, CDs of processing regions or patterns intended to be formed in the lower layer 110 and/or the substrate 100 may be precisely controlled, thereby improving dimensional precision. In addition, the CD distribution of patterns intended to be implemented on the substrate 100 may be uniformly controlled, and the dimensional precision of a pattern intended to be formed may be improved by minimizing LER and LWR of the pattern. Furthermore, excellent etch resistance and resolution may be provided in a photolithography process, and the productivity of a manufacturing process of an integrated circuit device may improve.

While the inventive concept has been particularly shown and described with reference to embodiments thereof, it will be understood that various changes in form and details may be made therein without departing from the spirit and scope of the following claims.

What is claimed is:

1. A photoresist composition comprising:
an organometallic complex comprising a metal element and a plurality of ligands bonded to the metal element, the plurality of ligands comprising at least two different ligands; and
a solvent,
wherein the plurality of ligands of the organometallic complex comprise:
at least one N,O-β-heteroarylalkenolate ligand having an oxygen atom and a nitrogen atom, the oxygen atom and the nitrogen atom each directly bonded to the metal element; and
at least one monodentate ligand bonded to the metal element.

2. The photoresist composition of claim 1, wherein the at least one N,O-β-heteroarylalkenolate ligand comprises a C1-C30 organic ligand having a pyridinyl group, an oxazolyl group, or a benzothiazolyl group.

3. The photoresist composition of claim 1, wherein the organometallic complex is represented by Formula 1: 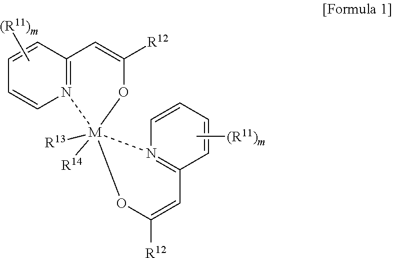
wherein, in Formula 1,
M is Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Fe, Ru, Pd, Ir, Ta, Nb, Cs, Ba, La, Ce, or Fe,
R¹¹ is a hydrogen atom, a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, a C2-C20 heteroaryl group, —Si(R^{a})(R^{b})(R^{c}), wherein each of R^{a}, R^{b}, and R^{c} is the same or different and is a C1-C6 alkyl group, or an amino group,
R¹² is a halogen element, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, a C6-C20 aralkyl group substituted with a fluorine atom or a fluoroalkyl group, a carboxylic acid group (—COOH), an aldehyde group (—CHO), an ester group (—COOR^{f}), a ketone group (—COR^{f}), a sulfone group (—SOOR^{f}), an amide group (—CONH₂), a cyano group (—CN), a sulfonate group (—SO₃H), or a nitro group (—NO₂), wherein R^{f} is a C1-C20 alkyl group substituted with a fluorine atom or a fluoroalkyl group,
R¹³ and R¹⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and
m is an integer of 1 to 4.

4. The photoresist composition of claim 1, wherein the organometallic complex is represented by Formula 2: 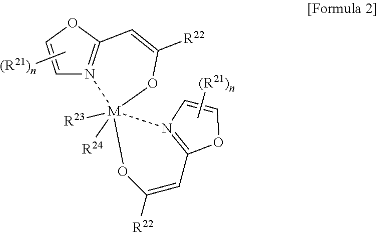
wherein, in Formula 2,
M is Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Fe, Ru, Pd, Ir, Ta, Nb, Cs, Ba, La, Ce, or Fe,
R²¹ is a hydrogen atom, a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, a C2-C20 heteroaryl group, —Si(R^{a})(R^{b})(R^{c}), wherein each of R^{a}, R^{b}, and R^{c} is the same or different and is a C1-C6 alkyl group, or an amino group,
R²² is a halogen element, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, a C6-C20 aralkyl group substituted with a fluorine atom or a fluoroalkyl group, a carboxylic acid group (—COOH), an aldehyde group (—CHO), an ester group (—COOR^{f}), a ketone group (—COR^{f}), a sulfone group (—SOOR^{f}), an amide group (—CONH₂), a cyano group (—CN), a sulfonate group (—SO₃H), or a nitro group (—NO₂), wherein R^{f} is a C1-C20 alkyl group substituted with a fluorine atom or a fluoroalkyl group,
R²³ and R²⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and
n is 1 or 2.

5. The photoresist composition of claim 1, wherein the organometallic complex is represented by Formula 3: 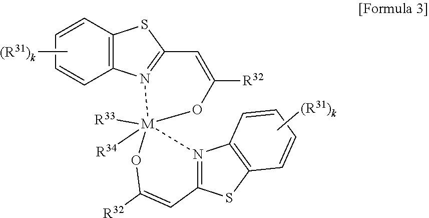
wherein, in Formula 3,
M is Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Fe, Ru, Pd, Ir, Ta, Nb, Cs, Ba, La, Ce, or Fe,
R³¹ is a hydrogen atom, a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, a C2-C20 heteroaryl group, —Si(R^{a})(R^{b})(R^{c}), wherein each of R^{a}, R^{b}, and R^{c} is the same or different and is a C1-C6 alkyl group, or an amino group,
R³² is a halogen element, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, a C6-C20 aralkyl group substituted with a fluorine atom or a fluoroalkyl group, a carboxylic acid group (—COOH), an aldehyde group (—CHO), an ester group (—COOR^{f}), a ketone group (—COR^{f}), a sulfone group (—SOOR^{f}), an amide group (—CONH₂), a cyano group (—CN), a sulfonate group (—SO₃H), or a nitro group (—NO₂), wherein R^{f} is a C1-C20 alkyl group substituted with a fluorine atom or a fluoroalkyl group,
R³³ and R³⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and
k is an integer of 1 to 4.

6. The photoresist composition of claim 1, wherein the solvent comprises a nonpolar organic solvent.

7. The photoresist composition of claim 1, further comprising a photoinitiator, the photoinitiator comprising at least one selected from a photoacid generator (PAG) configured to generate an acid in response to light and a photoradical generator (PRG) configured to generate a radical in response to light.

8. The photoresist composition of claim 1, further comprising at least one selected from a basic quencher, which comprises a compound capable of trapping an acid, and a radical quencher capable of trapping a radical.

9. A photoresist composition comprising an organometallic complex and a solvent
and configured to have a structural change of the organometallic complex in response to exposure to light,
wherein the organometallic complex comprises a metal element and a plurality of ligands bonded to the metal element and comprising at least two different ligands, and
the plurality of ligands comprise:
two N,O-β-heteroarylalkenolate ligands each having an oxygen atom and a nitrogen atom, the oxygen atom and the nitrogen atom each directly bonded to the metal element; and
at least one monodentate ligand comprising a C1 to C20 hydrocarbon group directly bonded to the metal element, the at least one monodentate ligand being configured to be dissociated from the metal element in response to exposure to light.

10. The photoresist composition of claim 9, wherein each of the two N,O-β-heteroarylalkenolate ligands each independently comprise a C1-C30 organic ligand having a pyridinyl group, an oxazolyl group, or a benzothiazolyl group.

11. The photoresist composition of claim 9, wherein the organometallic complex is represented by Formula 1: 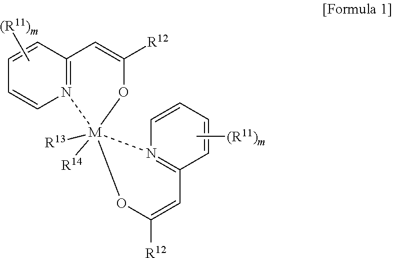
wherein, in Formula 1,
M is Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Fe, Ru, Pd, Ir, Ta, Nb, Cs, Ba, La, Ce, or Fe,
R¹¹ is an electron donating group and is a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, a C2-C20 heteroaryl group, —Si(R^{a})(R^{b})(R^{c}), wherein each of R^{a}, R^{b}, and R^{c} is the same or different and is a C1-C6 alkyl group, or an amino group,
R¹² is an electron withdrawing group and is a halogen element, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, a C6-C20 aralkyl group substituted with a fluorine atom or a fluoroalkyl group, a carboxylic acid group (—COOH), an aldehyde group (—CHO), an ester group (—COOR^{f}), a ketone group (—COR^{f}), a sulfone group (—SOOR^{f}), an amide group (—CONH₂), a cyano group (—CN), a sulfonate group (—SO₃H), or a nitro group (—NO₂), wherein R^{f} is a C1-C20 alkyl group substituted with a fluorine atom or a fluoroalkyl group,
R¹³ and R¹⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and
m is an integer of 1 to 4.

12. The photoresist composition of claim 9, wherein the organometallic complex is represented by Formula 2: 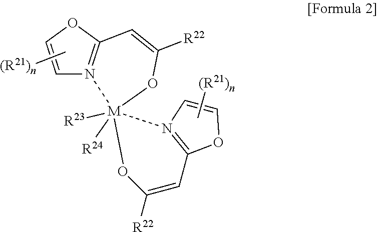
wherein, in Formula 2,
M is Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Fe, Ru, Pd, Ir, Ta, Nb, Cs, Ba, La, Ce, or Fe,
R²¹ is an electron donating group and is a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, a C2-C20 heteroaryl group, —Si(R^{a})(R^{b})(R^{c}), wherein each of R^{a}, R^{b}, and R^{c} is the same or different and is a C1-C6 alkyl group, or an amino group,
R²² is an electron withdrawing group and is a halogen element, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, a C6-C20 aralkyl group substituted with a fluorine atom or a fluoroalkyl group, a carboxylic acid group (—COOH), an aldehyde group (—CHO), an ester group (—COOR^{f}), a ketone group (—COR^{f}), a sulfone group (—SOOR^{f}), an amide group (—CONH₂), a cyano group (—CN), a sulfonate group (—SO₃H), or a nitro group (—NO₂), wherein R^{f} is a C1-C20 alkyl group substituted with a fluorine atom or a fluoroalkyl group,
R²³ and R²⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and
n is 1 or 2.

13. The photoresist composition of claim 9, wherein the organometallic complex is represented by Formula 3: 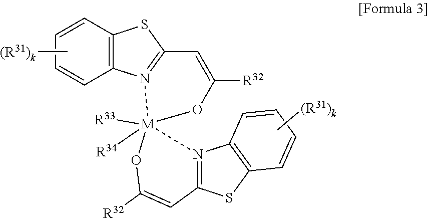
wherein, in Formula 3,
M is Sn, Sb, In, Bi, Ag, Te, Au, Pb, Zn, Ti, Hf, Zr, Al, V, Cr, Co, Ni, Cu, Ga, Mn, Cu, Sr, W, Cd, Mo, Fe, Ru, Pd, Ir, Ta, Nb, Cs, Ba, La, Ce, or Fe,
R³¹ is an electron donating group and is a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, a C2-C20 heteroaryl group, —Si(R^{a})(R^{b})(R^{c}), wherein each of R^{a}, R^{b}, and R^{c} is the same or different and is a C1-C6 alkyl group, or an amino group,
R³² is an electron withdrawing group and is a halogen element, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, a C6-C20 aralkyl group substituted with a fluorine atom or a fluoroalkyl group, a carboxylic acid group (—COOH), an aldehyde group (—CHO), an ester group (—COOR′), a ketone group (—COR^{f}), a sulfone group (—SOOR^{f}), an amide group (—CONH₂), a cyano group (—CN), a sulfonate group (—SO₃H), or a nitro group (—NO₂), wherein R′ is a C1-C20 alkyl group substituted with a fluorine atom or a fluoroalkyl group,
R³³ and R³⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group, and
k is an integer of 1 to 4.

14. The photoresist composition of claim 9, further comprising a photoinitiator comprising at least one selected from a photoacid generator (PAG) configured to generate an acid in response to light and a photoradical generator (PRG) configured to generate a radical in response to light.

15. The photoresist composition of claim 9, further comprising at least one selected from a basic quencher, which comprises a compound capable of trapping an acid, and a radical quencher capable of trapping a radical.

16. A method of manufacturing an integrated circuit device, the method comprising:
forming a photoresist film on a substrate from a photoresist composition comprising a plurality of organometallic complexes and a solvent, wherein each of the plurality of organometallic complexes comprises a metal element and a plurality of ligands boned to the metal element and comprising at least two different ligands, and the plurality of ligands of each of the plurality of organometallic complexes comprise at least one N,O-β-heteroarylalkenolate ligand having an oxygen atom and a nitrogen atom, the oxygen atom and the nitrogen atom each directly bonded to the metal element, and at least one monodentate ligand bonded to the metal element;
exposing an unshared electron pair of the metal element by exposing a first area to light, wherein the metal element is a portion of the photoresist film, to thereby dissociate the at least one monodentate ligand from each of the plurality of organometallic complexes selectively only in the first area of the photoresist film;
forming an organometallic structure network in the first area by inducing crystal growth of bonded structures between the at least one N,O-β-heteroarylalkenolate ligand and the metal element comprising the exposed unshared electron pair in the first area exposed to light; and
forming a photoresist pattern comprising the organometallic structure network by developing the photoresist film in which the organometallic structure network is formed.

17. The method of claim 16, wherein, in the forming of the photoresist film, the at least one N,O-β-heteroarylalkenolate ligand comprises a C1-C30 organic ligand having a pyridinyl group, an oxazolyl group, or a benzothiazolyl group.

18. The method of claim 16, wherein, in the forming of the photoresist film, each of the plurality of organometallic complexes is selected from Formulae 1, 2, 3, and 4: 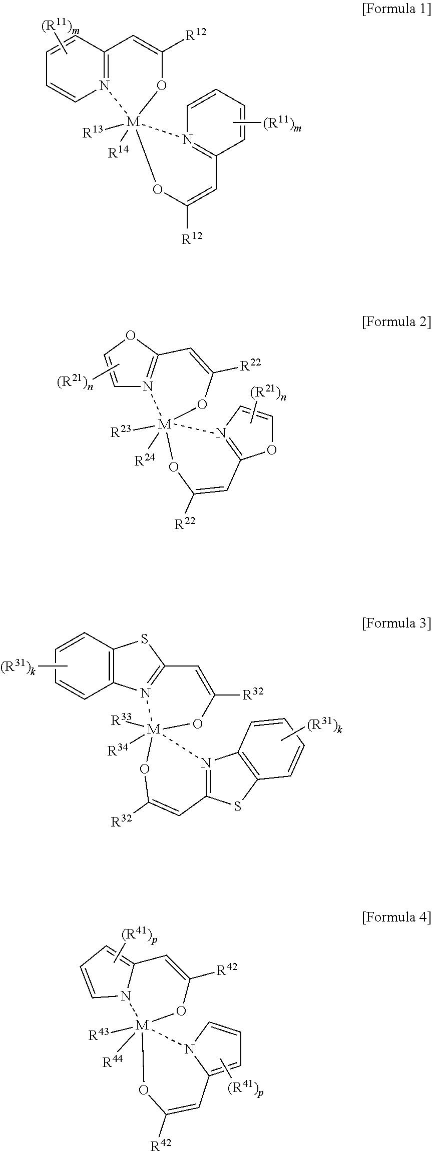
wherein, in Formulae 1, 2, 3, and 4,
M is Sn, Sb, In, Bi, Ag, Tc, Au, Pb, Zn, Ti, Hf, Zr, Al, V, Cr, Co, Ni, Cu, Ga, Mn, Cu, Sr, W, Cd, Mo, Fc, Ru, Pd, Ir, Ta, Nb, Cs, Ba, La, Ce, or Fc,
R¹¹, R²¹, R³¹, and R⁴¹ are each a hydrogen atom, a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, a C2-C20 heteroaryl group, —Si(R^{a})(R^{b})(R^{c}), wherein each of R^{a}, R^{b}, and R^{c} is the same or different and is a C1-C6 alkyl group, or an amino group,
R¹², R²², R³², and R⁴² are each a halogen element, a C1-C20 alkyl group substituted with a fluorine atom or a fluoroalkyl group, a C1-C20 alkoxy group substituted with a fluorine atom or a fluoroalkyl group, a C6-C20 aryl group substituted with a fluorine atom or a fluoroalkyl group, a C6-C20 aralkyl group substituted with a fluorine atom or a fluoroalkyl group, a carboxylic acid group (—COOH), an aldehyde group (—CHO), an ester group (—COOR^{f}), a ketone group (—COR^{f}), a sulfone group (—SOOR^{f}), an amide group (—CONH₂), a cyano group (—CN), a sulfonate group (—SO₃H), or a nitro group (—NO₂), wherein R^{f} is a C1-C20 alkyl group substituted with a fluorine atom or a fluoroalkyl group,
R¹³, R¹⁴, R²³, R²⁴, R³³, R³⁴, R⁴³, and R⁴⁴ are each independently a C1-C20 linear alkyl group, a C1-C20 branched alkyl group, a C2-C20 alkenyl group, a C2-C20 alkynyl group, a C3-C20 cycloalkyl group, a C1-C20 alkoxy group, a C6-C20 aryl group, or a C2-C20 heteroaryl group,
m is an integer of 1 to 4,
n is 1 or 2,
k is an integer of 1 to 4, and
p is an integer of 1 to 3.

19. The method of claim 16, wherein, in the forming of the photoresist film, the photoresist composition further comprises a photoinitiator, the photoinitiator comprising at least one selected from a photoacid generator (PAG) configured to generate an acid in response to light and a photoradical generator (PRG) configured to generate a radical in response to light.

20. The method of claim 16, wherein the exposing of the first area to light comprises exposing the first area to light by using an extreme ultraviolet (EUV) wavelength (13.5 nm).
